(19) United States
(12) Patent Application Publication
(10) Pub. No.: US 2022/0109032 A1
(43) Pub. Date: Apr. 7, 2022

(54) OLED DISPLAY STRUCTURE AND ELECTRONIC EQUIPMENT

(71) Applicant: SHENZHEN ROYOLE TECHNOLOGIES CO., LTD., SHENZHEN (CN)

(72) Inventor: Qiangcan HUANG, SHENZHEN (CN)

(73) Assignee: SHENZHEN ROYOLE TECHNOLOGIES CO., LTD., SHENZHEN (CN)

(21) Appl. No.: 17/421,304

(22) PCT Filed: Jan. 7, 2019
(86) PCT No.: PCT/CN2019/070693

§ 371 Date: Jul. 7, 2021

(51) Int. Cl. H01L 27/32

(52) U.S. Cl. CPC H01L 27/3218; H01L 27/3262; H01L 27/3265

(57) ABSTRACT

The present application discloses an OLED display structure, including pixels. The pixels include a first sub-pixel, a second sub-pixel and a third sub-pixel. The first sub-pixel includes a first storage capacitor, a first auxiliary capacitor and a first light emitting area. The second sub-pixel includes a second storage capacitor, a second auxiliary capacitor and a second light emitting area. The third sub-pixel includes a third storage capacitor, a third auxiliary capacitor and a third light emitting area. The areas of the first light emitting area, the second light emitting area and the third light emitting area are respectively defined as S (1), S (2) and S (3); the capacitance values of the first auxiliary capacitor, the second auxiliary capacitor and the third auxiliary capacitor are respectively defined as C2(1), C2(2) and C2(3). S(1)<S(2)<S(3), and C2(1)>C2(2)>C2(3).

### TECHNICAL FIELD

The present disclosure relates to the field of display technology, in particular to an OLED display structure and electronic equipment.

### BACKGROUND ART

In the existing OLED display structure, the threshold voltage (Vₜₕ) of the thin film transistor (TFT) is prone to drift phenomenon when the positive voltage is applied for a long time, the change of Vₜₕ will eventually cause the current of the OLED to change, and for the three colors of red, green and blue (R/G/B) of the OLED display structure, due to the different light emitting areas of the three colors of R/G/B, the changing speed of the OLED current on the three colors of R/G/B varied with Vₜₕ is not consistent, the finally presented R/G/B brightness changing speed is also inconsistent, which easily leads to the color offset problem of the OLED display structure.

### SUMMARY

The technical solutions of the present disclosure disclose an OLED display structure and electronic equipment with uniform color rendering.

An OLED display structure comprises pixels, the pixels include a first sub-pixel, a second sub-pixel and a third sub-pixel, the first sub-pixel comprises a first storage capacitor, a first auxiliary capacitor and a first light emitting area, the second sub-pixel comprises a second storage capacitor, a second auxiliary capacitor and a second light emitting area, and the third sub-pixel comprises a third storage capacitor, a third auxiliary capacitor and a third light emitting area, the area of the first light emitting area is defined as S(1), the area of the second light emitting area is defined as S(2), and the area of the third light emitting area is defined as S(3), the capacitance value of the first auxiliary capacitor is defined as C2(1), the capacitance value of the second auxiliary capacitor is defined as C2(2), and the capacitance value of the third auxiliary capacitor is defined as C2(3), wherein S(1)<S(2)<S(3), and C2(1)>C2(2)>C2(3).

An electronic equipment includes the above-mentioned OLED display structure.

In the OLED display structure and electronic equipment of the present disclosure, by setting C2(1)>C2(2)>C2(3), it can compensate for the difference of the changing speed of R/G/B OLED current under different Vₜₕ, so the problem of color offset is not easy to occur.

### BRIEF DESCRIPTION OF DRAWINGS

In order to illustrate technical solutions in the embodiments of the present disclosure more clearly, the drawings to be used in the embodiment will be briefly introduced below, obviously, the drawings in the following description are only some embodiments of the present disclosure, for those ordinarily skilled in the art, other drawings can also be obtained in light of these drawings, without using any inventive efforts.

FIG. 1 is a structural schematic view of an OLED display structure in a first embodiment of the present disclosure.

FIG. 2 is a schematic view of a 4T2C pixel driving circuit for a sub-pixel of the OLED display structure in the first embodiment of the present disclosure.

FIG. 3 is a schematic view of another 4T2C pixel driving circuit for a sub-pixel of the OLED display structure in the first embodiment of the present disclosure.

FIG. 4 is a schematic view of an electronic equipment including the OLED display structure in a second embodiment of the present disclosure.

FIG. 5 is a schematic view of the changing speed of the R/G/B OLED current under different Vₜₕ in the prior art.

FIG. 6 is a schematic view of the changing speed of the R/G/B OLED current under different Vₜₕ in the present technical solution.

### DETAILED DESCRIPTION OF EMBODIMENTS

The technical solutions in the embodiment of the present disclosure will be clearly and completely described below in combination with the drawings in the embodiments of the technical solutions of the present disclosure. Obviously, the described embodiments are only a part of the embodiments of the present disclosure, not all the embodiments. Based on the embodiments of the present disclosure, all other embodiments obtained by those ordinary skilled in the art without creative work shall fall within the protection scope of the present disclosure.

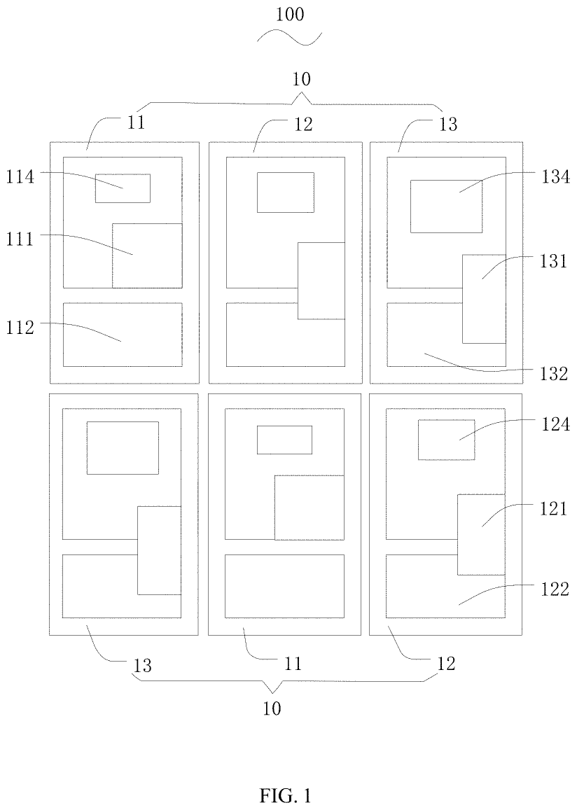

Please refer to FIG. 1, the first embodiment of the present technical solution provides an OLED display structure 100, the OLED display structure 100 includes a plurality of pixels 10 (only two pixels 10 are shown in the figure), and each pixel 10 includes a first sub-pixel 11, a second sub-pixel 12, and a third sub-pixel 13.

Each sub-pixel includes a storage capacitor, an auxiliary capacitor, and an organic light emitting diode, each sub-pixel also has a light emitting area, wherein the lighting emitting areas of three sub-pixels have different areas, among the three sub-pixels, the larger the area of the lighting emitting area is, the smaller the auxiliary capacitance value of the sub-pixel is.

Specifically, as shown in FIG. 1 of the present embodiment, the first sub-pixel 11 includes a first storage capacitor 111, a first auxiliary capacitor 112 and a first organic light emitting diode (not shown), and the first organic light emitting diode enables the first sub-pixel 11 to have a first light emitting area 114, or in other words, the first organic light emitting diode is provided in the first light emitting area 114; the second sub-pixel 12 includes a second storage capacitor 121, a second auxiliary capacitor 122 and a second organic light emitting diode (not shown), the second organic lighting emitting diode enables the second sub-pixel 12 to have a second light emitting area 124, or in other words, the second organic light emitting diode is provided in the second light emitting area 124; the third sub-pixel 13 includes a third storage capacitor 131, a third auxiliary capacitor 132, and a third organic light emitting diode (not shown), the third organic light emitting diode enables the third sub-pixel 13 to have a third light emitting area 134, or in other words, the third organic light emitting diode is provided in the third light emitting area 134. It can be understood that, in other embodiments, the structure of each sub-pixel is not limited to the present embodiment.

The area of the first light emitting area 114 of the first sub-pixel 11 is defined as S(1), the area of the second light emitting area 124 of the second sub-pixel 12 is defined as S(2), and the area of the third light emitting area 134 of the third sub-pixel 13 is defined as S(3), the capacitance value of the first auxiliary capacitor 112 corresponding to the first sub-pixel 11 is defined as C2(1), the capacitance value of the second auxiliary capacitor 122 corresponding to the second sub-pixel 12 is defined as C2(2), and the capacitance value of the third auxiliary capacitor 132 corresponding to the third sub-pixel 13 is defined as C2(3), then S(1)<S(2)<S(3), and C2(1)>C2(2)>C2(3).

Further, the capacitance value of the first storage capacitor 111 corresponding to the first sub-pixel 11 is defined as C1(1), the capacitance value of the first storage capacitor 121 corresponding to the second sub-pixel 12 is defined as C1(2), and the capacitance value of the first storage capacitor 131 corresponding to the third sub-pixel 13 is defined as C1(3), then C1(1)=C1(2)=C1(3).

In this embodiment, the capacitance value of the capacitor is adjusted by adjusting the area of the capacitor.

As shown in FIG. 1, the areas of the first, second, and third auxiliary capacitors are different, and thus the capacitance values are also different, among the three sub-pixels of each pixel 10, the area of the first auxiliary capacitor 112 is the largest, the area of the third auxiliary capacitor 132 is the smallest, so that the capacitance value C2(1) of the first auxiliary capacitor 112 is the largest, and the capacitance value C2(3) of the third auxiliary capacitor 132 is the smallest, that is, the area of the first auxiliary capacitor 112 is larger than the area of the second auxiliary capacitor 122, the area of the second auxiliary capacitor 122 is larger than the area of the third auxiliary capacitor 132; although the shapes of the first, second, and third storage capacitors 111, 121, and 131 are different, the areas are the same, and thus the capacitance values are also the same.

The first sub-pixel 11, the second sub-pixel 12, and the third sub-pixel 13 may be three primary color sub-pixels respectively, that is, one of the red, green and blue sub-pixels.

In this embodiment, the first sub-pixel 11 is a red sub-pixel, the second sub-pixel 12 is a green sub-pixel, and the third sub-pixel 13 is a blue sub-pixel.

Each sub-pixel further includes a plurality of transistors, and preferably, each sub-pixel includes at least 4 thin film transistors.

In this embodiment, each sub-pixel includes four thin film transistors, one storage capacitor, one auxiliary capacitor, and at least one organic light emitting diode, that is, in this embodiment, the pixel driving circuit of each sub-pixel is a 4T2C pixel driving circuit.

In one embodiment, four thin film transistors are respectively a driving thin film transistor and three switching thin film transistors.

In one embodiment, the driving thin film transistor includes a gate electrode, a source electrode, and a drain electrode, and the storage capacitor is connected between the gate electrode and the drain electrode of the driving thin film transistor.

In one embodiment, the auxiliary capacitor is connected between a switching thin film transistor and the driving thin film transistor, and the switching thin film transistor is configured to receive a reference voltage; for example, the auxiliary capacitor is connected between the source electrode of the switching thin film transistor and the drain electrode of the driving thin film transistor, or is connected between the drain electrode of the switching thin film transistor and the source electrode of the driving thin film transistor.

In one embodiment, the anode of the organic light emitting diode is electrically connected to the drain electrode of the driving thin film transistor.

Preferably, the thin film transistors of the technical solution are all of the top gate structure, that is, the gate electrode is on the upper side of the channel layer, and the source and drain electrodes are on the lower side of the channel layer.

The following uses an embodiment to describe in detail a 4T2C pixel driving circuit of a sub-pixel:

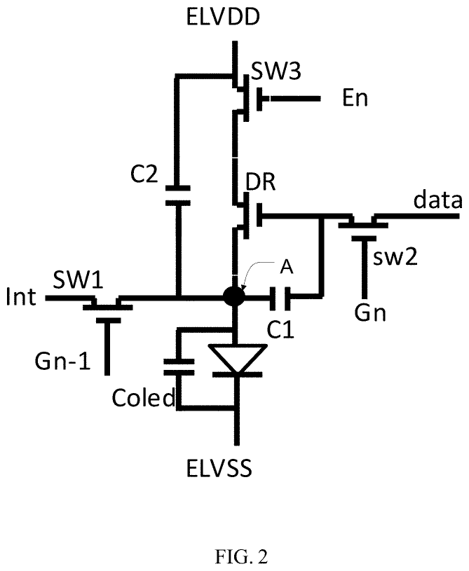

Please refer to FIG. 2, a 4T2C pixel driving circuit 20 includes a first switching thin film transistor SW1, a second switching thin film transistor SW2, a third switching thin film transistor SW3, a driving thin film transistor DR, a storage capacitor C1, an auxiliary capacitor C2 and an organic light emitting diode OLED.

The first, second, and third switching thin film transistors SW1, SW2, and SW3 and the driving thin film transistor DR all include a gate electrode, a drain electrode and a source electrode, wherein the gate electrode of the first switching thin film transistor SW1 is configured to receive the previous-level gate signal Gn−1, the source electrode is configured to receive an input signal Int, and the drain electrode is electrically connected to the node A. The gate electrode of the second switching thin film transistor SW2 is configured to receive a gate signal Gn, the drain electrode is electrically connected to the gate electrode of the driving thin film transistor DR, the source electrode is configured to receive a data signal Data, wherein the data signal has a data voltage. The gate electrode of the third switching thin film transistor SW3 is configured to be electrically connected to the control main line En, the drain electrode is electrically connected to the source electrode of the driving thin film transistor DR, and the drain electrode is electrically connected to a first reference voltage ELVDD. The gate electrode of the driving thin film transistor DR is electrically connected to the drain electrode of the second switching thin film transistor SW2, the drain electrode is electrically connected to the node A, and the source electrode is electrically connected to the source electrode of the third switching thin film transistor SW3.

The storage capacitor C1 is bridged between the gate electrode and the drain electrode of the driving thin film transistor DR. The auxiliary capacitor C2 is bridged between the source electrode of the third switching thin film transistor SW3 and the node A (the drain electrode of the driving thin film transistor DR).

The organic light emitting diode OLED includes an anode and a cathode, the anode of the organic light emitting diode OLED is electrically connected to the drain electrode of the driving thin film transistor DR, and the cathode is electrically connected to a second reference voltage ELVSS. In this embodiment, a filter capacitor C3 is connected in parallel between the anode and the cathode of the organic light emitting diode OLED.

The following uses another embodiment to describe in detail another 4T2C pixel driving circuit of a sub-pixel.

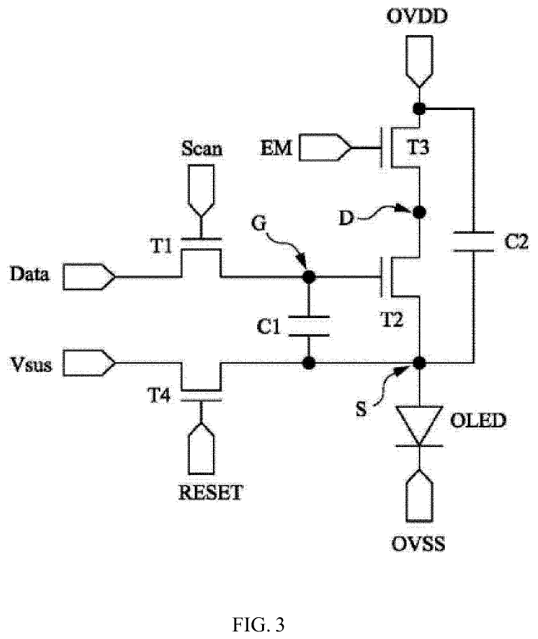

Please refer to FIG. 3, a 4T2C pixel driving circuit 30 includes a first switching thin film transistor T1, a driving thin film transistor T2, a second switching thin film transistor T3, a third switching thin film transistor T4, a storage capacitor C1, an auxiliary capacitor C2 and an organic light emitting diode OLED.

In an embodiment, the driving thin film transistor T2 and the first, second, and third switching thin film transistors T1, T3, and T4 are all N-type thin film transistors.

The gate electrode of the first switching thin film transistor T1 is configured to receive a scan signal (Scan), source electrode is configured to receive a data signal Data (the data signal Data represents a data voltage), and the drain electrode is electrically connected to the node G. The gate electrode of the driving thin film transistor T2 is electrically connected to the drain electrode of the first switching thin film transistor T1 and the node G, the drain electrode is electrically connected to the drain electrode of the second switching thin film transistor T3 and the node D, and the drain electrode is electrically connected to the node S. The gate electrode of the second switching thin film transistor T3 receives a switching signal EM, the source electrode is electrically connected to a first reference voltage OVDD. The gate electrode of third switching thin film transistor T4 receives a reset signal RESET, the source electrode receives a sustain voltage signal Vsus, and the drain electrode is electrically connected to the node S.

The anode of the organic light emitting diode OLED is electrically connected to the node S (the drain electrode of the driving thin film transistor T2), and the cathode is electrically connected to a second reference voltage OVSS, wherein the first reference voltage OVDD is greater than the second reference voltage OVSS.

The storage capacitor C1 is bridged between the node G (the gate electrode of the driving thin film transistor T2) and the node S (the drain electrode of the driving thin film transistor T2); the auxiliary capacitor C2 is bridged between the source electrode of the second switching thin film transistor T3 and the node S (the drain electrode of the driving thin film transistor T2).

In other embodiments, each of the sub-pixels may also include five thin film transistors, six thin film transistors or even more, that is, the pixel driving circuit of the sub-pixel may also be 5T2C pixel driving circuit, and 6T2C pixel driving circuit, and the like.

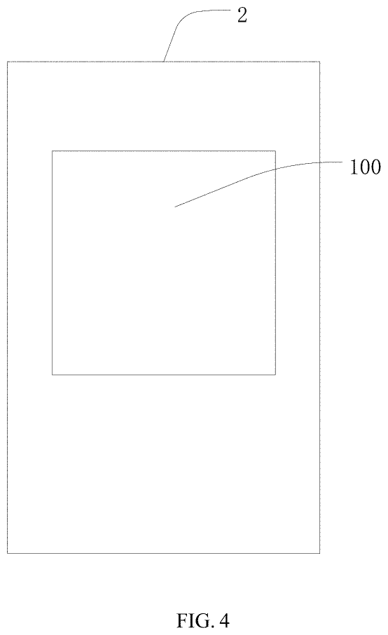

Please refer to FIG. 4, the second embodiment of the present technical solution further provides an electronic equipment 2, and the electronic equipment 2 includes the aforementioned OLED display structure 100.

In the above, the electronic equipment 2 may be a mobile phone, a tablet computer, and an e-book, and the like.

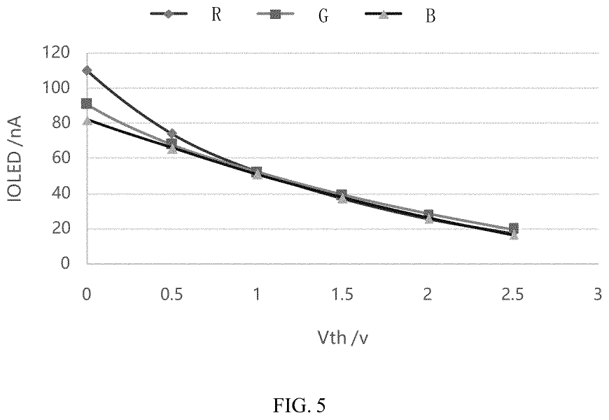

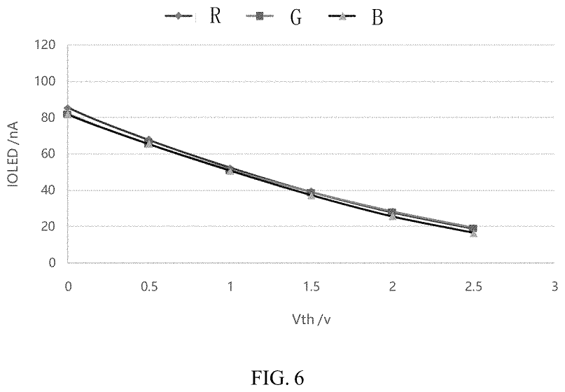

In the prior art, the changing speed of R/G/B OLED current under different Vₜₕ is not consistent, as shown in FIG. 5 (the abscissa is the threshold voltage Vₜₕ, the unit is volt V, the ordinate is the current I_{OLED}, the unit is nanoampere nA; the same as in FIG. 6), especially between 0V and 0.8V, the changing speed of the R/G/B OLED current is obviously different; in the OLED display structure of the present technical solution, by setting C2(1)>C2(2)>C2(3), so as to compensate for the difference on changing speed of R/G/B OLED current under different Vₜₕ, as shown in FIG. 6, in the simulation experiment of the present technical solution, the consistency of changes of the R/G/B OLED current under different Vₜₕ is better, between 0V and 0.8V, the changing speed of R/G/B OLED current is basically the same. Therefore, the problem of color offset is not easy to occur in the OLED display structure of the present technical solution.

The above are the preferred embodiments of the present disclosure, it should be pointed out that for those ordinarily skilled in the art, without departing from the principle of the present disclosure, several improvements and modifications can also be made, and these improvements and modifications are also considered to be within the protection scope of the present disclosure.

1. An OLED display structure, comprising pixels, wherein the pixels comprise a first sub-pixel, a second sub-pixel and a third sub-pixel, the first sub-pixel comprises a first storage capacitor, a first auxiliary capacitor and a first light emitting area, the second sub-pixel comprises a second storage capacitor, a second auxiliary capacitor and a second light emitting area, and the third sub-pixel comprises a third storage capacitor, a third auxiliary capacitor and a third light emitting area, wherein an area of the first light emitting area is defined as S(1), an area of the second light emitting area is defined as S(2), and an area of the third light emitting area is defined as S(3), a capacitance value of the first auxiliary capacitor is defined as C2(1), a capacitance value of the second auxiliary capacitor is defined as C2(2), and a capacitance value of the third auxiliary capacitor is defined as C2(3), wherein S(1)<S(2)<S(3), and C2(1)>C2(2)>C2(3).

2. The OLED display structure according to claim 1, wherein an area of the first auxiliary capacitor is larger than an area of the second auxiliary capacitor, and the area of the second auxiliary capacitor is larger than an area of the third auxiliary capacitor.

3. The OLED display structure according to claim 1, wherein a capacitance value of the first storage capacitor is defined as C1(1), a capacitance value of the second storage capacitor is defined as C1(2), and a capacitance value of the third storage capacitor is defined as C1(3), wherein C1(1)=C1(2)=C1(3).

4. The OLED display structure according to claim 3, wherein areas of the first storage capacitor, the second storage capacitor, and the third storage capacitor are the same.

5. The OLED display structure according to claim 4, wherein the first storage capacitor, the second storage capacitor, and the third storage capacitor are of different shapes.

6. The OLED display structure according to claim 1, wherein the first sub-pixel is a red sub-pixel, the second sub-pixel is a green sub-pixel, and the third sub-pixel is a blue sub-pixel.

7. The OLED display structure according to claim 1, wherein the first sub-pixel, the second sub-pixel, and the third sub-pixel all comprise four thin film transistors, one storage capacitor, one auxiliary capacitor, and at least one organic light emitting diode, wherein one of the four thin film transistors is a driving thin film transistor.

8. The OLED display structure according to claim 7, wherein the driving thin film transistor comprises a gate electrode, a source electrode and a drain electrode, and the storage capacitor is connected between the gate electrode and the drain electrode of the driving thin film transistor.

9. The OLED display structure according to claim 7, wherein the auxiliary capacitor is connected between a switching thin film transistor and the driving thin film transistor, and the switching thin film transistor is configured to receive a reference voltage.

10. The OLED display structure according to claim 9, wherein the auxiliary capacitor is connected between a source electrode of the switching thin film transistor and the source electrode of the driving thin film transistor, or is connected between a drain electrode of the switching thin film transistor and the source electrode of the driving thin film transistor.

11. The OLED display structure according to claim 7, wherein an anode of the organic light emitting diode is electrically connected to the drain electrode of the driving thin film transistor.

12. The OLED display structure according to claim 7, wherein the first sub-pixel, the second sub-pixel, and the third sub-pixel all comprise a first switching thin film transistor, a second switching thin film transistor, a third switching thin film transistor, the driving thin film transistor, the storage capacitor, the auxiliary capacitor and the organic light emitting diode, wherein the first switching thin film transistor, the second switching thin film transistor and the third switching thin film transistor all comprise a gate electrode, a drain electrode, and a source electrode, wherein the gate electrode of the first switching thin film transistor is configured to receive a previous-level gate signal, the source electrode is configured to receive an input signal, and the drain electrode is electrically connected to a node; the gate electrode of the second switching thin film transistor is configured to receive a gate signal, the source electrode is configured to receive a data signal, the drain electrode is electrically connected to a gate electrode of the driving thin film transistor, wherein the data signal has a data voltage; the gate electrode of the third switching thin film transistor is configured to be electrically connected to a control main line, the source electrode is electrically connected to a first reference voltage, and the drain electrode is electrically connected to a source electrode of the driving thin film transistor; and the driving thin film transistor comprise the gate electrode, a drain electrode and the source electrode, the gate electrode of the driving thin film transistor is electrically connected to the drain electrode of the second switching thin film transistor, and the source electrode is electrically connected to the drain electrode of the third switching thin film transistor, the drain electrode is electrically connected to the node.

13. The OLED display structure according to claim 12, wherein the storage capacitor is bridged between the gate electrode and the drain electrode of the driving thin film transistor; and the auxiliary capacitor is bridged between the source electrode of the third switching thin film transistor and the drain electrode of the driving thin film transistor DR.

14. The OLED display structure according to claim 12, wherein the organic light emitting diode comprises an anode and a cathode, the anode of the organic light emitting diode is electrically connected to the drain electrode of the driving thin film transistor, and the cathode is electrically connected to a second reference voltage.

15. The OLED display structure according to claim 12, wherein a filter capacitor is connected in parallel between the anode and the cathode of the organic light emitting diode.

16. The OLED display structure according to claim 7, wherein the first sub-pixel, the second sub-pixel, and the third sub-pixel all comprise a first switching thin film transistor, the driving thin film transistor, a second switching thin film transistor, a third switching thin film transistor, the storage capacitor, the auxiliary capacitor and the organic light emitting diode, wherein the first switching thin film transistor, the driving thin film transistor, the second switching thin film transistor and the third switching thin film transistor all comprise a gate electrode, a drain electrode and a source electrode; the gate electrode of the first switching thin film transistor is configured to receive a scan signal, and the source electrode receives a data signal; the gate electrode of the driving thin film transistor is electrically connected to the drain electrode of the first switching thin film transistor, and is electrically connected to the storage capacitor, the source electrode is electrically connected to the drain electrode of the second switching thin film transistor; the gate electrode of the second switching thin film transistor receives a switching signal, the source electrode is electrically connected to a first reference voltage; and the gate electrode of the third switching thin film transistor receives a reset signal, the source electrode receives a sustain voltage signal, and the drain electrode is electrically connected to the drain electrode of the driving thin film transistor.

17. The OLED display structure according to claim 16, wherein the storage capacitor is bridged between the gate electrode and the drain electrode of the driving thin film transistor, and the auxiliary capacitor is bridged between the source electrode of the second switching thin film transistor and the drain electrode of the driving thin film transistor.

18. The OLED display structure according to claim 16, wherein the organic light emitting diode comprises an anode and a cathode, the anode of the organic light emitting diode is electrically connected to the drain electrode of the driving thin film transistor, and the cathode is electrically connected to a second reference voltage.

19. An electronic equipment, wherein the electronic equipment comprises the OLED display structure according to claim 1.

20. The electronic equipment according to claim 19, wherein the electronic equipment comprises a mobile phone, a tablet computer and an e-book.
